(19) United States
(12) Patent Application Publication
(10) Pub. No.: US 2026/0236353 A1
(43) Pub. Date: Aug. 13, 2026

(54) MANAGING AN OPERATING MODE OF AN INFORMATION HANDLING SYSTEM

(71) Applicant: Dell Products L.P., Round Rock, TX (US)

(72) Inventors: Laxmi Lavanya Medicherla, Georgetown, TX (US); Ibrahim Sayyed, Georgetown, TX (US); Alan Helmy Abdelhalim, Pflugerville, TX (US)

(21) Appl. No.: 19/052,690

(22) Filed: Feb. 13, 2025

(51) Int. Cl. G06F 11/14; G06F 11/26

(52) U.S. Cl. CPC G06F 11/1446; G06F 11/26

(57) ABSTRACT

Managing an operating mode of an information handling system, including identifying a current operating mode of the information handling system; receiving telemetry events of the information handling system, including telemetry events associated with an update or a repair to computing hardware of the information handling system; monitoring, based on the telemetry events, one or more parameters of the computing hardware, including: performing a diagnostic test of the computing hardware; analyzing results of the diagnostic test, including determining whether the computing hardware is fully functional based on the diagnostic test; and determining that the computing hardware is fully functional, and in response, reverting the current operating mode of the information handling system to a previous operating mode of the information handling system.

### BACKGROUND

### Field of the Disclosure

The disclosure relates generally to an information handling system, and in particular, managing an operating mode of an information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Hardware repair involves diagnosing and fixing issues with physical components of a computer, such as the motherboard, hard drive, or power supply. Ensuring compatibility between components is crucial for a stable and efficient system.

### SUMMARY

Innovative aspects of the subject matter described in this specification may be embodied in a method of managing an operating mode of an information handling system, including identifying a current operating mode of the information handling system; receiving telemetry events of the information handling system, including telemetry events associated with an update or a repair to computing hardware of the information handling system; monitoring, based on the telemetry events, one or more parameters of the computing hardware, including: performing a diagnostic test of the computing hardware; analyzing results of the diagnostic test, including determining whether the computing hardware is fully functional based on the diagnostic test; and determining that the computing hardware is fully functional, and in response, reverting the current operating mode of the information handling system to a previous operating mode of the information handling system.

Other embodiments of these aspects include corresponding systems, apparatus, and computer programs, configured to perform the actions of the methods, encoded on computer storage devices.

These and other embodiments may each optionally include one or more of the following features. For instance, determining that the computing hardware is not fully functional, and in response, maintaining the current operating mode of the information handling system. The previous operating mode of the information handling system is based on user-configured settings. A performance level of the previous operating mode is greater than a performance level of the current operating mode. The performance level includes a processing capacity of the information handling system. Monitoring the one or more parameters of the computing hardware further includes: generating, based on the telemetry events, a dynamic batch request; and performing the diagnostic test based on the dynamic batch request. Accessing a firmware interface of the information handling system; verifying, based on the firmware interface, that the computing hardware was updated or repaired; and in response to the verification, generating the dynamic batch request. Determining a time period from when the computer hardware was updated or repaired to a current time; comparing the time period to a threshold; and determining that the time period is greater than the threshold, and in response, analyzing the results of the diagnostic test.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of an information handling system for managing the operating mode of the information handling system.

FIG. 3 illustrates a method for managing the operating mode of the information handling system.

### DESCRIPTION OF PARTICULAR EMBODIMENT(S)

This disclosure discusses methods and systems for managing an operating mode of an information handling system. In short, traditional repair approaches of computing hardware often configure the information handling system to “limp along” and leave it in a limited state, even if the underlying issue that caused the problem was temporary or later fixed by an operating system (OS) or firmware update. The system described here automatically reconfigures the information handling system back to full performance/features—after a health monitoring/quarantine period and diagnostic tests to ensure it is safe to do so. Specifically, the solution set resides in a software service within the OS of the information handling system. This service scans the BIOS-presented telemetry events, which contain information about system encounters and mitigations that occurred in the underlying OS. Next, it analyzes and creates an action plan in terms of a “telemetry batch request” to further monitor and ensure the health of the computing hardware is in good condition. When the diagnostic results for the computing hardware provide enough confidence, it configures the computing hardware and firmware back to an optimal performance mode.

Specifically, this disclosure discusses a system and a method for managing an operating mode of an information handling system, including identifying a current operating mode of the information handling system; receiving telemetry events of the information handling system, including telemetry events associated with an update or a repair to computing hardware of the information handling system; monitoring, based on the telemetry events, one or more parameters of the computing hardware, including: performing a diagnostic test of the computing hardware; analyzing results of the diagnostic test, including determining whether the computing hardware is fully functional based on the diagnostic test; and determining that the computing hardware is fully functional, and in response, reverting the current operating mode of the information handling system to a previous operating mode of the information handling system.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

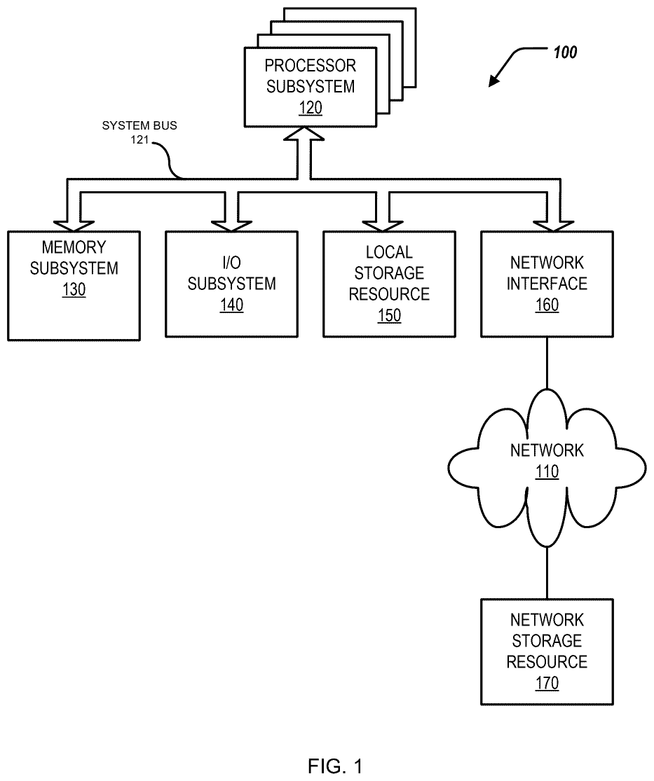

Particular embodiments are best understood by reference to FIGS. 1-3 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

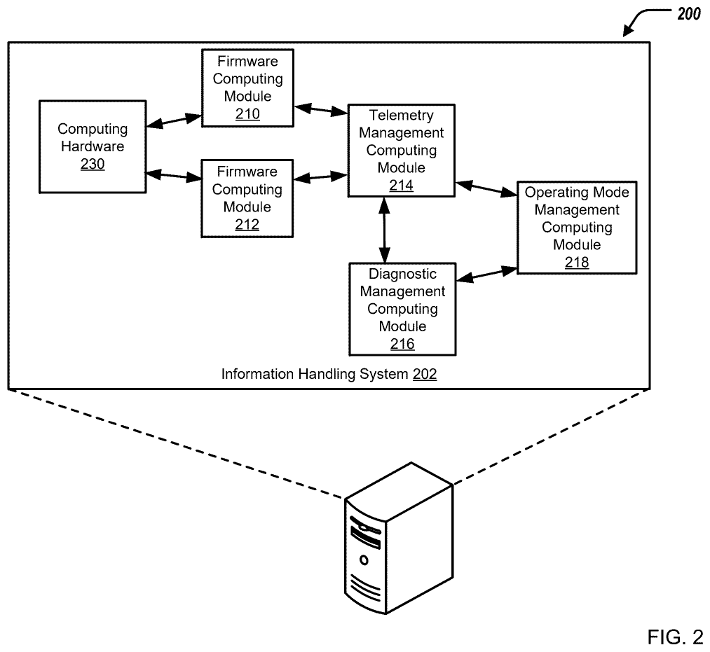

Turning to FIG. 2, FIG. 2 illustrates an environment 200 including an information handling system 202. The information handling system 202 can include firmware computing modules 210, 212; a telemetry management computing module 214, a diagnostic management computing module 216, and an operating mode management computing module 218. The information handling system 202 can further include computing hardware 230. In some examples, the information handling system 202 is similar to, or includes, the information handling system 100 of FIG. 1.

The computing hardware 230 can include memory, hard disk drives, processors, and the like.

The firmware computing modules 210, 212 can include Basic Input/Output System (BIOS) firmware, Unified Extensible Firmware Interface (UEFI) firmware, and the like.

The firmware computing modules 210, 212 can be in communication with the telemetry management computing module 214 and the computing hardware 230. The telemetry management computing module 214 can be in communication with the firmware computing modules 210, 212, the diagnostic management computing module 216, and the operating mode management computing module 218. The diagnostic management computing module 216 can be in communication with the telemetry management computing module 214 and the operating mode management computing module 218. The operating mode management computing module 218 can be in communication with the telemetry management computing module 214 and the diagnostic management computing module 216.

In short, traditional repair approaches of the computing hardware 230 often configure the information handling system 202 to “limp along” and leave it in a limited state, even if the underlying issue that caused the problem was temporary or later fixed by an operating system (OS) or firmware update. The system described here automatically reconfigures the information handling system 202 back to full performance/features—after a health monitoring/quarantine period and diagnostic tests to ensure it is safe to do so. Specifically, the solution set resides in a software service within the OS of the information handling system 202. This service scans the BIOS-presented telemetry events, which contain information about system encounters and mitigations that occurred in the underlying OS. Next, it analyzes and creates an action plan in terms of a “telemetry batch request” to further monitor and ensure the health of the computing hardware are in good condition. When the diagnostic results for the computing hardware provide enough confidence, it configures the computing hardware and firmware back to an optimal performance mode.

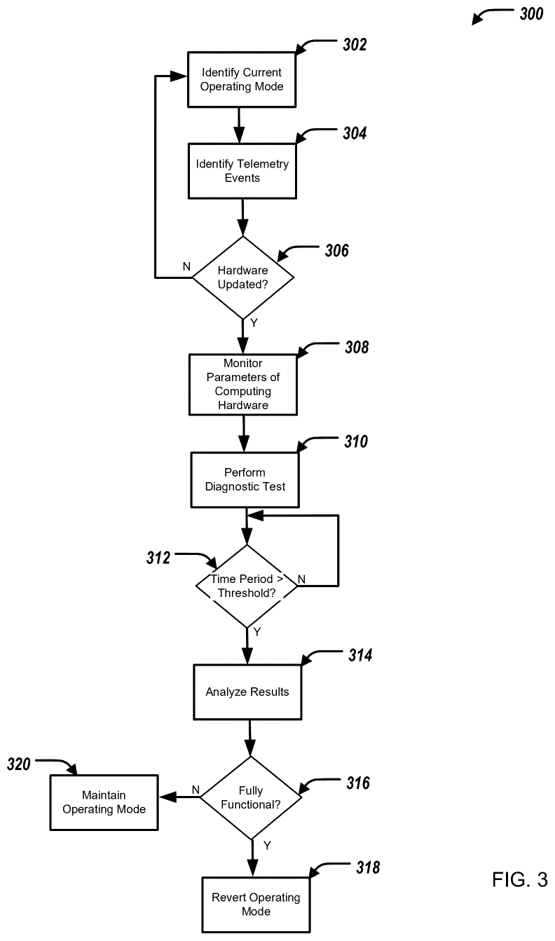

FIG. 3 illustrates a flowchart depicting selected elements of an embodiment of a method 300 for managing the operating mode of the information handling system. The method 300 may be performed by the information handling system 100, the information handling system 202, and/or the firmware computing modules 210, 212; the telemetry management computing module 214, the diagnostic management computing module 216, and the operating mode management computing module 218, and with reference to FIGS. 1-2. It is noted that certain operations described in method 300 may be optional or may be rearranged in different embodiments.

The operating mode management computing module 218 identifies a current operating mode of the information handling system 202, at 302. In some examples, the current operating mode of the information handling system 202 can be based on user-configured settings that are related to power management of the information handling system 202 and/or the computing hardware 230; performance of the information handling system 202 and/or the computing hardware 230; and/or security of the information handling system 202 and/or the computing hardware 230. In some examples, the current operating mode of the information handling system 202 can include a battery-saver mode of the information handling system 202, a performance mode of the information handling system 202, an ultra (or high) performance mode of the information handling system 202, or a balanced mode of the information handling system 202. Each operating mode of the information handling system 202 can be associated with corresponding computational performance parameters, battery performance parameters, and/or security performance parameters.

In some examples, the current operating mode of the information handling system 202 can include a decreased performance operating mode of the information handling system 202. In some examples, the current operating mode of the information handling system 202 can include a sub-optimal performance operating mode of the information handling system 202. In some examples, the current operating mode of the information handling system 202 can include settings that are not user configured. In some examples, the current operating mode of the information handling system 202 can include default or factory settings.

The telemetry management computing module 214 can receive telemetry events of the information handling system 202, at 304. Specifically, the firmware computing modules 210, 212 can present telemetry events related to hardware repairs and/or hardware updates and mitigation that has been applied to the computing hardware 230 to the telemetry management computing module 214. That is, the telemetry events are associated with an update or a repair to the computing hardware 230 of the information handling system 202. The telemetry events can be Basic Input/Output System (BIOS) events, Unified Extensible Firmware Interface (UEFI) events, or the like. The telemetry management computing module 214 can access the firmware computing modules 210, 212 (firmware interface) to receive the telemetry events of the information handling system 202.

The telemetry management computing module 214 can collect the data indicating the telemetry events associated with the computing hardware 230, and provide such to the operating mode management computing module 218. The operating mode management computing module 218 determines whether the computing hardware 230 was updated and/or repaired, at 306. Specifically, the operating mode management computing module 218 determines whether the computing hardware 230 was updated and/or repaired based on the telemetry events from the firmware computing modules 210, 212.

In some examples, the computing hardware 230 can be updated and/or repaired to have the information handling system 202 back to an operational state (e.g., from an inoperative state). However, during the update/repair and/or after the update/repair, the operating mode (system configuration) of the information handling system 202 may be altered or reduced to perform such updates/repairs of the computing hardware 230. For example, the operating mode (system configuration) of the information handling system 202 can be updated to remove user-configured settings related to the power, performance, and/or security of the information handling system 202 when the computing hardware 230 is updated or repaired. For example, the operating mode (system configuration) of the information handling system 202 can be updated to a factory operating mode (or reduced performance operating mode) when the computing hardware 230 is updated or repaired.

In some examples, the operating mode management computing module 218 determines that the computing hardware 230 has been updated (at 306), and in response, monitors, based on the telemetry events, parameters of the computing hardware 230, at 308. Specifically, the operating mode management computing module 218 generates, based on the telemetry events, a dynamic batch request. The dynamic batch request can include a scheduled health scan of the computing hardware 230. That is, in response to verifying that the computing hardware 230 has been updated or repaired (at 306), the operating mode management computing module 218 generates the dynamic batch request to monitor parameters of the computing hardware 230.

The operating mode management computing module 218 provides instructions to the diagnostic management computing module 216 to perform a diagnostic test of the computing hardware 230. The diagnostic management computing module 216 performs the diagnostic test of the computing hardware 230, at 310. That is, the diagnostic management computing module 216 performs the diagnostic test of the computing hardware 230 based on the dynamic batch request. The diagnostic management computing module 216 can perform the diagnostic test of the computing hardware 230 in headless mode based on the dynamic batch request. The diagnostic management computing module 216 can provide data indicating the results of the diagnostic test to the telemetry management computing module 214.

The operating mode management computing module 218 determines a time period from when the computing hardware 230 was updated or repaired to a current time. The operating mode management computing module 218 compares the time period to a threshold, at 312. That is, the operating mode management computing module 218 determines whether a threshold amount of time has elapsed from the repair or update to the computing hardware 230. In some examples, the operating mode management computing module 218 determines that the time period is greater than the threshold (at 312), and in response, analyzes the results of the diagnostic test, at 314. Specifically, the operating mode management computing module 218 determines whether the computing hardware 230 is fully functional based on the diagnostic test, at 316. In other words, the operating mode management computing module 218 determines whether the computing hardware 230 is ready to operate at an optimal performance level. In other words, the operating mode management computing module 218 determines whether the computing hardware 230 is able to operate at a performance level/operating mode/system configuration that was associated with the information handling system 202 prior to the update/repair of the computing hardware 230.

In some examples, the operating mode management computing module 218 determines that the computing hardware 230 is fully functional based on the diagnostic test (at 316), and in response, reverts the current operating mode of the information handling system 202 to a previous operating mode of the information handling system 202, at 318. That is, when the results of the diagnostic test for the computing hardware 230 indicate that the computing hardware 230 is able to operate at a performance level/operating mode/system configuration that was associated with the information handling system 202 prior to the update/repair of the computing hardware 230, the operating mode management computing module 218 reverts the current operating mode of the information handling system 202 to the previous operating mode of the information handling system 202.

In some examples, the previous operating mode of the information handling system 202 is based on user-configured settings. That is, the previous operating mode of the information handling system 202 can be based on user-configured settings of performance, security, or power. In some examples, the performance level of the previous operating mode (of step 318) is greater than a performance level of the current operating mode (of step 302). In some examples, the performance level is a processing capacity of the information handling system 202. That is, the processing capacity of the previous operating mode (of step 318) is greater than a processing capacity of the current operating mode (of step 302). The processing capacity can include CPU frequency, or calculations per minute, or the like. In some examples, the performance level is a memory allocation/availability of the information handling system 202. That is, the memory allocation/availability of the previous operating mode (of step 318) is greater than the memory allocation/availability of the current operating mode (of step 302).

In some examples, the operating mode management computing module 218 determines that the computing hardware 230 is not fully functional based on the diagnostic test (at 316), and in response, maintains the current operating mode of the information handling system 202, at 320. That is, when the results of the diagnostic test for the computing hardware 230 indicate that the computing hardware 230 is not able to operate at a performance level/operating mode/system configuration that was associated with the information handling system 202 prior to the update/repair of the computing hardware 230, the operating mode management computing module 218 maintains the current operating mode of the information handling system 202.

In some examples, the operating mode management computing module 218 determines that the computing hardware 230 has not been updated (at 306), e.g., based on the telemetry events, and in response, returns to step 302.

In some examples, the operating mode management computing module 218 determines that the time period is not greater than the threshold (at 312), and in response, returns to step 312.

In a use case, the computing hardware 230 can include two memory modules. The memory modules are having issues with a reduced memory capacity. The firmware computing modules 210, 212 detect a boot-time issue related to the memory modules. The firmware computing modules 210 and/or 212 identifies one of the memory modules as problematic, and blocks the probabilistic memory module from being a part of the system memory (a DIMM module of the memory modules). The memory module can be problematic from such issues as a misconfiguration of the memory module, loose connector connections of the memory module, or issues with the memory module itself. Despite the memory issues, the information handling system 202 continues to boot, and operates with a reduced memory (only one of the memory modules is available—e.g., 4 GB as opposed to the full 8 GB). The telemetry management computing module 214, the diagnostic management computing module 216, and/or the operating mode management computing module 218 continues to monitor, analyze, and perform health diagnostics of the memory modules. The modules determine that the issue can be resolved through an in-band or out-of-band managed update. The diagnostic management computing module 216 then performs a health scan of the memory module to determine if it is healthy and full functional to be included as system memory. If the memory module is health, the operating mode management computing module 218 signals to include the memory module, resulting in a cold reboot and the system booting with the full memory (e.g., 8 GB).

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

1. A computer-implemented method of managing an operating mode of an information handling system, including:
identifying a current operating mode of the information handling system;
receiving telemetry events of the information handling system, the telemetry events including Basic Input/Output System (BIOS) events and Unified Extensible Firmware Interface (UEFI) events;
determining that the telemetry events indicate an update to a computing hardware of the information handling system, the computing hardware including a processor or memory;
in response to determining that telemetry events indicate the update to the computing hardware of the information handling system, monitoring one or more parameters of the computing hardware, including:
performing a diagnostic test of the computing hardware;
analyzing results of the diagnostic test, including determining whether the computing hardware is fully functional based on the diagnostic test; and
determining that the computing hardware is fully functional, and in response, reverting the current operating mode of the information handling system to a previous operating mode of the information handling system.

2. The computer-implemented method of claim 1, further including:
determining that the computing hardware is not fully functional, and in response, maintaining the current operating mode of the information handling system.

3. The computer-implemented method of claim 2, wherein the previous operating mode of the information handling system is based on user-configured settings.

4. The computer-implemented method of claim 2, wherein a performance level of the previous operating mode is greater than a performance level of the current operating mode.

5. The computer-implemented method of claim 4, wherein the performance level includes a processing capacity of the information handling system.

6. The computer-implemented method of claim 1, wherein monitoring the one or more parameters of the computing hardware further includes:
generating, based on the telemetry events, a dynamic batch request; and
performing the diagnostic test based on the dynamic batch request.

7. The computer-implemented method of claim 6, further including:
accessing a firmware interface of the information handling system;
verifying, based on the firmware interface, that the computing hardware was updated or repaired; and
in response to the verification, generating the dynamic batch request.

8. The computer-implemented method of claim 1, further including:
determining a time period from when the computing hardware was updated or repaired to a current time;
comparing the time period to a threshold; and
determining that the time period is greater than the threshold, and in response, analyzing the results of the diagnostic test.

9. An information handling system comprising a processor having access to memory media storing instructions executable by the processor to perform operations, comprising:
identifying a current operating mode of the information handling system;
receiving telemetry events of the information handling system, the telemetry events including Basic Input/Output System (BIOS) events and Unified Extensible Firmware Interface (UEFI) events;
determining that the telemetry events indicate an update to a computing hardware of the information handling system, the computing hardware including a processor or memory;
in response to determining that telemetry events indicate the update to the computing hardware of the information handling system, monitoring one or more parameters of the computing hardware, including:
performing a diagnostic test of the computing hardware;
analyzing results of the diagnostic test, including determining whether the computing hardware is fully functional based on the diagnostic test; and
determining that the computing hardware is fully functional, and in response, reverting the current operating mode of the information handling system to a previous operating mode of the information handling system.

10. The information handling system of claim 9, the operations further including:
determining that the computing hardware is not fully functional, and in response, maintaining the current operating mode of the information handling system.

11. The information handling system of claim 10, wherein the previous operating mode of the information handling system is based on user-configured settings.

12. The information handling system of claim 10, wherein a performance level of the previous operating mode is greater than a performance level of the current operating mode.

13. The information handling system of claim 12, wherein the performance level includes a processing capacity of the information handling system.

14. The information handling system of claim 9, wherein monitoring the one or more parameters of the computing hardware further includes:
generating, based on the telemetry events, a dynamic batch request; and
performing the diagnostic test based on the dynamic batch request.

15. The information handling system of claim 14, the operations further including:
accessing a firmware interface of the information handling system;
verifying, based on the firmware interface, that the computing hardware was updated or repaired; and
in response to the verification, generating the dynamic batch request.

16. The information handling system of claim 9, the operations further including:
determining a time period from when the computer hardware was updated or repaired to a current time;
comparing the time period to a threshold; and
determining that the time period is greater than the threshold, and in response, analyzing the results of the diagnostic test.

17. A non-transitory computer-readable medium storing software comprising instructions executable by one or more computers which, upon such execution, cause the one or more computers to perform operations comprising:
identifying a current operating mode of an information handling system;
receiving telemetry events of the information handling system, the telemetry events including Basic Input/Output System (BIOS) events and Unified Extensible Firmware Interface (UEFI) events;
determining that the telemetry events indicate an update to a computing hardware of the information handling system, the computing hardware including a processor or memory;
in response to determining that telemetry events indicate the update to the computing hardware of the information handling system, monitoring one or more parameters of the computing hardware, including:
performing a diagnostic test of the computing hardware;
analyzing results of the diagnostic test, including determining whether the computing hardware is fully functional based on the diagnostic test; and
determining that the computing hardware is fully functional, and in response, reverting the current operating mode of the information handling system to a previous operating mode of the information handling system.

18. The non-transitory computer-readable medium of claim 17, the operations further including:
determining that the computing hardware is not fully functional, and in response, maintaining the current operating mode of the information handling system.

19. The non-transitory computer-readable medium of claim 18, wherein the previous operating mode of the information handling system is based on user-configured settings.

20. The non-transitory computer-readable medium of claim 18, wherein a performance level of the previous operating mode is greater than a performance level of the current operating mode.
